(19) United States
(12) Patent Application Publication
(10) Pub. No.: US 2003/0011053 A1
(43) Pub. Date: Jan. 16, 2003

(54) Semiconductor device

(75) Inventor: Masatoshi Yasunaga, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/057,923

(22) Filed: Jan. 29, 2002

(30) Foreign Application Priority Data
Jul. 12, 2001 (JP) 2001-211915

(51) Int. Cl. H01L 23/02

(52) U.S. Cl. 257/678

(57) ABSTRACT

The present invention provides a semiconductor device comprising a substrate, a semiconductor chip mounted on the substrate, external electrodes placed on the back of the substrate and for connecting electrodes of the semiconductor chip to the outside, a sealing member for encapsulating the semiconductor chip on the substrate, and a heat sink plate fixed with the sealing member. In the semiconductor device, the heat sink plate is disposed so as to be opposed to a main surface on which semiconductor elements of the semiconductor chip are formed.

### BACKGROUND OF THE INVENTION

1. Field of the Invention

The present invention relates to a semiconductor device. More specifically, the present invention relates to a semiconductor device having a heat dissipation structure and to improve in heat dissipation efficiency.

2. Background Art

With a great increase in the storage capacity of a memory of a semiconductor device, multi-functioning of logic thereof and high integration thereof, power consumption of the semiconductor device has been increased in recent years. The increase in power consumption can result in an increase in the amount of heat generated from the semiconductor device, thus causing a rise in the temperature of the semiconductor device. A problem arises in that the rise in the temperature of the semiconductor device would lead to degradation of the characteristic of the semiconductor device and a decrease in reliability thereof. Thus, there have been proposed various semiconductor devices each provided with a heat dissipation structure with a view toward improving the problem incident to the rise in the temperature of such a semiconductor device.

FIG. 7 is a sectional typical view for describing one example of a semiconductor device having the already-existing heat dissipation mechanism. FIG. 8 is a sectional typical view for describing one example of a semiconductor device having an already-existing heat dissipation fin.

In FIG. 7, a semiconductor chip 12 is electrically connected to inner leads 25A by bonding wires 23 inside a sealing member 24. Each of the inner leads 25A is continuously connected to its corresponding outer lead 25B provided outside the sealing member 24. The outer leads 25B respectively serve as external electrode terminals for connecting a semiconductor device 700 and external electrodes.

Further, a heat sink plate 7 is provided to cause heat generated from the semiconductor chip 12 to escape to the outside efficiently and is fixed to the semiconductor device 700 by the sealing member 24. The heat sink plate 7 is formed of a material good in thermal conductivity, such as aluminum, copper or the like to dissipate the heat efficiently. Most of the heat generated in the semiconductor chip 12 is thermally transferred to the heat sink plate 7 and dissipated heat from a surface of the heat sink plate 7, which is exposed from the sealing member 24.

As shown in FIG. 7, concavo-convex portions 7A are provided on the surface of the heat sink plate 7 exposed from the sealing member 24. Owing to the provision of the concavo-convex portions 7A, the surface area at which the heat sink plate 7 makes contact with the outside increases, thus making it possible to dissipate the heat more efficiently.

As an alternative to the above, as shown in FIG. 8, there is known a semiconductor device 800 wherein a feather-shaped heat dissipation fin 8A is provided on a surface of a heat sink plate 8, which is exposed from a sealing member 24. The area at which the heat sink plate contacts with the outside is increased similarly even by the present semiconductor device, so that heat can be dissipated with efficiency.

However, since the heat generated upon operation of a semiconductor device with multi-functioning and high integration of the semiconductor device becomes increasingly high, there has been a demand for a heat dissipation structure capable of dissipating the heat more efficiently. While an increase in the size of a heat sink plate is also considered to dissipate the heat more efficiently, a limitation is imposed on the size of the heat sink plate attached to the semiconductor device from restraints on the whole size of an electrical apparatus comprising a combination of semiconductor devices, etc.

With the high integration, etc., the number of leads mounted to one semiconductor device increases. Thus, since each individual lead becomes thin and is hence short in strength, an increase in the contact area with the outside by increasing such a heat dissipation fin 8A as described in FIG. 8 is also hard to consider.

On the other hand, in such a conventional semiconductor device 700 or 800 as shown in FIG. 7 or 8, the heat sink plate 7 or 8 is disposed so as to be opposed to a surface opposite to a main surface 12A on which semiconductor elements of the semiconductor chip 12 are provided. However, a location where the heat is generated in the semiconductor chip 12, concentrates on the portion of the main surface 12A formed with the semiconductor elements. The main surface 12A corresponds to the most surface layer of the semiconductor chip 12, whose surface is about 10 μm. Namely, in order to thermally conduct the heat generated in the main surface 12A of the most surface layer into the heat sink plate 7 or 8 mounted to the semiconductor device 700 or 800 and dissipate it out, the heat must be transferred to the heat sink plate 7 or 8 through a layer of the semiconductor chip below the main surface 12A. Accordingly, a problem arises in that the distance for the thermal conduction becomes long by the thickness of the semiconductor chip 12 and hence the efficiency of dissipation of the heat becomes low.

### SUMMARY OF THE INVENTION

As described above, there has been a demand for the efficient dissipation to restrain a rise in the temperature of the semiconductor device. However, a simple increase in the size of the heat sink plate is hard to consider from the viewpoint of the restraint on the size of the whole electrical apparatus comprised of the combination of the semiconductor devices and the shortage of the strength of each lead mounted to the semiconductor device. In order to dissipate the heat generated in the main surface on which the semiconductor elements of the semiconductor chip are formed, through the heat sink plate, the heat must be thermally conducted through the semiconductor chip per se and transferred to the heat sink plate. Therefore, the efficiency of dissipation of the heat becomes low.

Thus, the present invention aims to solve the problems and propose a semiconductor device having a heat dissipation mechanism capable of rapidly transferring heat produced in the semiconductor device to a heat sink plate, and dissipating a larger quantity of heat more efficiently.

According to one aspect of the present invention, a semiconductor device comprises a substrate, a semiconductor chip mounted on the substrate, external electrodes provided on the back of the substrate, for connecting electrodes of the semiconductor chip to the outside, a sealing member for encapsulating the semiconductor chip on the substrate, and a heat sink plate fixed by the sealing member. The heat sink plate has concavo-convex portions formed on an exposed surface thereof and is disposed so as to be opposed to a main surface formed with semiconductor elements of the semiconductor chip.

According to another aspect of the present invention, a semiconductor device comprises a substrate, a semiconductor chip mounted on the substrate, external electrodes provided on the back of the substrate, for connecting electrodes of the semiconductor chip to the outside, a sealing member for encapsulating the semiconductor chip on the substrate, and a heat sink plate fixed by the sealing member. The heat sink plate has a heat radiating or heat dissipating fin formed integrally therewith.

Other and further objects, features and advantages of the invention will appear more fully from the following description.

### BRIEF DESCRIPTION OF THE DRAWINGS

FIG. 1 is a sectional typical view for describing a semiconductor device according to a first embodiment of the present invention;

FIG. 2 is a sectional typical view for describing a semiconductor device according to a second embodiment of the present invention;

FIG. 3 is a sectional typical view for describing a semiconductor device according to a third embodiment of the present invention;

FIG. 4 is a sectional typical view for describing a semiconductor device according to a fourth embodiment of the present invention;

FIG. 5 is a sectional typical view for describing a semiconductor device according to a fifth embodiment of the present invention;

FIG. 6 is a sectional typical view for describing a semiconductor device according to a sixth embodiment of the present invention;

FIG. 7 is a sectional typical view for describing one example of a semiconductor device having the already-existing heat dissipation mechanism;

FIG. 8 is a sectional typical view for describing one example of a semiconductor device having an already-existing heat dissipation fin.

### DETAILED DESCRIPTION OF THE PREFERRED EMBODIMENTS

Embodiments of the present invention will hereinafter be described with reference to the accompanying drawings. Incidentally, the same or equivalent portions in the respective drawings are identified by the same reference numerals and their description will therefore be simplified or omitted.

### First Embodiment

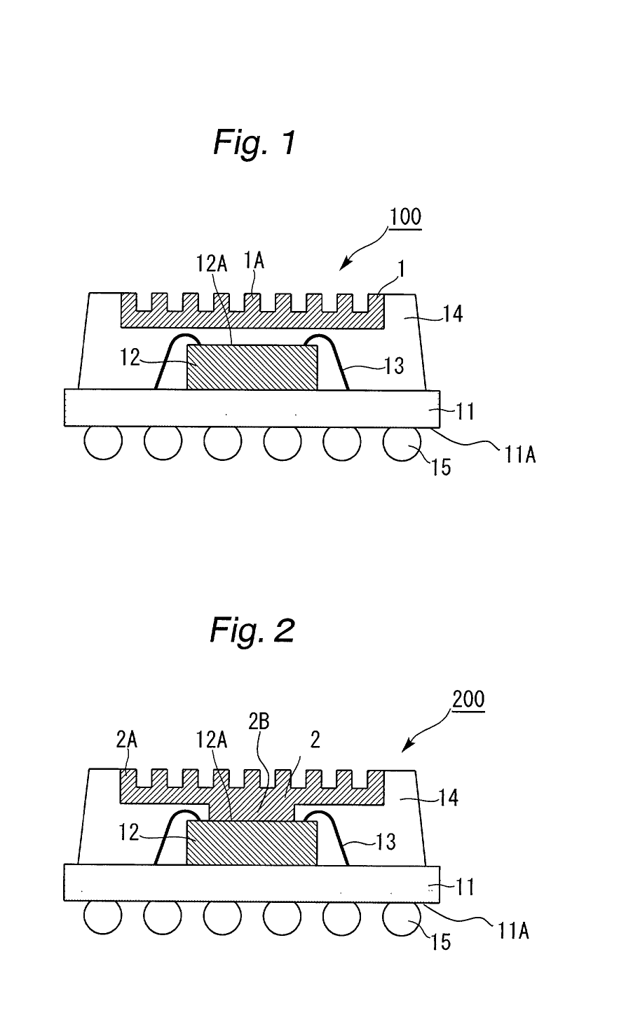

FIG. 1 is a sectional typical view for describing a semiconductor device according to a first embodiment of the present invention.

In FIG. 1, reference numeral 100 indicates the semiconductor device according to the present embodiment.

Reference numeral 11 indicates a substrate, and reference numeral 12 indicates a semiconductor chip placed on the substrate 11. Reference numeral 12A indicates a main surface with semiconductor elements of the semiconductor chip 12 formed thereon.

Reference numerals 13 indicate connecting wires for respectively connecting element electrodes (not shown) formed on the main surface 12A and electrodes (not shown) formed on the substrate 11. Reference numerals 15 indicate external electrode terminals provided on a reverse side or back 11A of the substrate 11. The external electrode terminals 15 are used to connect the semiconductor device 100 according to the present embodiment and external electrodes.

The semiconductor chip 12 is capable of performing the transfer of electric signals to the outside through the external electrode terminals 15, the electrodes on the substrate, the connecting wires 13 and the element electrodes on the main surface 12A.

Reference numeral 14 indicates a sealing member. The sealing member 14 is used to avoid the semiconductor chip from making contact with the outside thereof and thereby enhance reliability.

Further, reference numeral 1 indicates a heat sink plate fixed to the semiconductor device 100 by the sealing member 14. The heat sink plate 1 is provided to dissipate heat generated in the semiconductor chip more efficiently. Accordingly, the heat sink plate 1 is formed of a material good in thermal conductivity, such as aluminum, copper or the like.

Reference numerals 1A indicate concavo-convex portions provided on the surface exposed from the sealing member 14. Owing to the concavo-convex portions 1A, the surface area at which the heat sink plate 1 makes contact with the outside, increases, whereby the efficiency of heat dissipation is also increased.

Further, the heat sink plate 1 and the main surface 12A of the semiconductor chip are formed in an opposing relationship with a thin layered portion of the sealing member 14 being interposed therebetween. Namely, the semiconductor chip 12 is placed on the substrate 11 in such a manner that the heat sink plate 1 is disposed on the same side as the main surface 12A, and the semiconductor chip makes contact with the substrate 11 at the surface opposite to the main surface 12A.

A portion highest in the generated heat, of the semiconductor chip 12 normally corresponds to the main surface 12A formed with the semiconductor elements, which corresponds to the most surface layer equivalent to 10 μm, of the semiconductor chip 12. Thus, if the heat sink plate 1 and the main surface 12A are disposed so as to adjoin each other as described in the present embodiment, then the transfer of the heat generated in the main surface 12A to the heat sink plate 1 is faster than in the case where the heat sink plate 1 is disposed in opposition to the surface opposite to the main surface 12A, and hence the heat can be dissipated with efficiency.

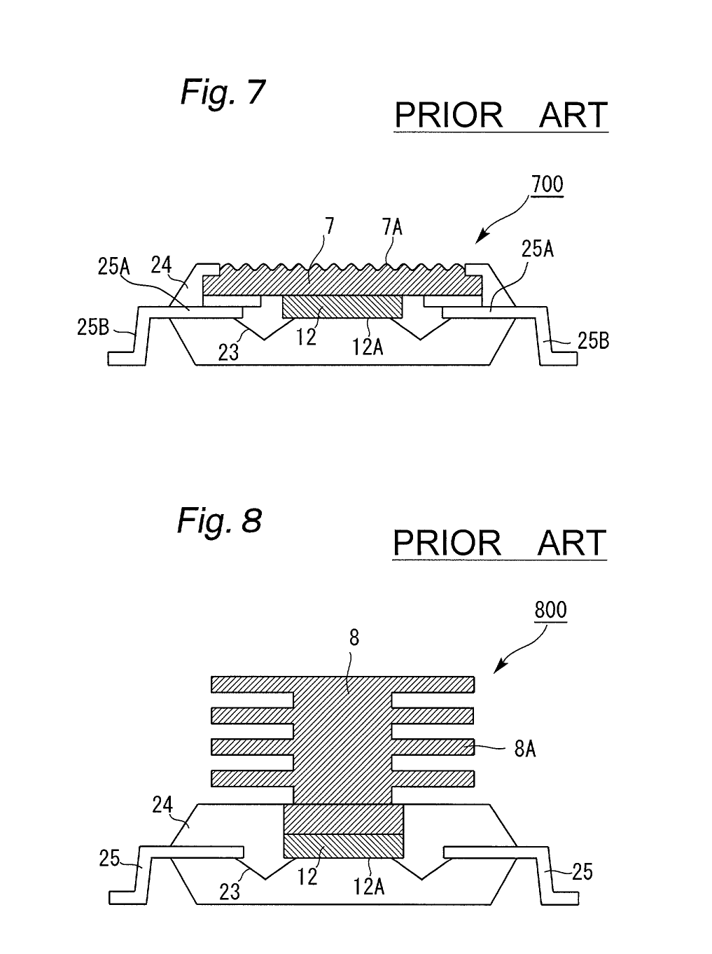

According to the first embodiment, the external electrode terminals can be provided over the whole back 11A of the substrate 11. Thus, as compared with such a semiconductor device as shown in FIG. 7, which has the lead frames which protrude from the sides thereof, the semiconductor device can be reduced in size over its entirety. Further, the present embodiment is capable of acquiring lots of leads and coping with the scale down and multi-functioning of the semiconductor device. In addition, since the external electrode terminals 15 can be provided over the whole back 11A with allowance in this way, it is not necessary to break up each individual external electrode terminal as in the case of the lead frames. Even if the heat sink plate 1 has a certain degree of size, it does not lose a strength equivalent to such a strength that it is capable of enduring a load applied to the heat sink plate 1.

Incidentally, while the connecting wires 13 for respectively connecting the electrodes located above the substrate 11 and the electrodes on the main surface 12A of the semiconductor chip have been used in the first embodiment, the present invention is not limited to it. Any one may be used if ones capable of performing connections between the two are adopted.

### Second Embodiment

FIG. 2 is a sectional typical view for describing a semiconductor device according to a second embodiment of the present invention.

In FIG. 2, reference numeral 200 indicates the semiconductor device according to the second embodiment.

Reference numeral 2 indicates a heat sink plate fixedly secured to the semiconductor device 200 by a sealing member 14. The heat sink plate 2 has concavo-convex portions 2A f or increasing an area where it makes contact with the outside, which are provided on the surface exposed from the sealing member 14. Further, the heat sink plate 2 has a connecting portion 2B provided on the side opposite to the concavo-convex portions 2A, i.e., the side opposite to a main surface 12A of the semiconductor chip. The heat sink plate 2 i s disposed so as to make contact with the main surface 12A at the surface of the connecting portion 2B.

Since other portions are similar to those employed in the first embodiment, their description will therefore be omitted.

According to the present embodiment, the heat sink plate 2 and the main surface 12A corresponding to a portion most increased in the generated heat, of the semiconductor chip 12 are disposed so as to make direct contact with each other or contact each other through a thin protective film when the thin protective film is formed on the main surface 12A of the semiconductor chip. Accordingly, the heat generated in the main surface 12A of the semiconductor chip can be made conductive to the heat sink plate 2 directly and promptly. Further, the heat can be dissipated more efficiently.

### Third Embodiment

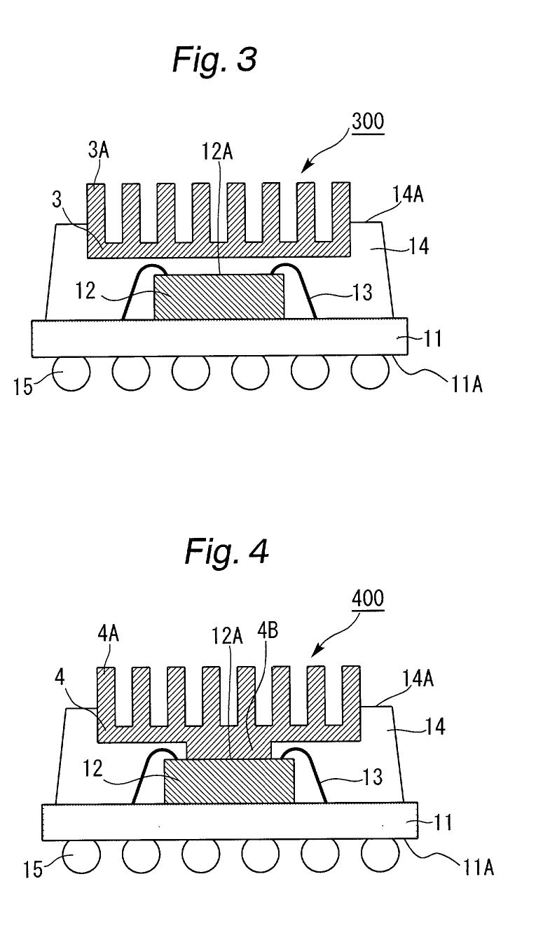

FIG. 3 is a sectional typical view for describing a semiconductor device according to a third embodiment of the present invention.

In FIG. 3, reference numeral 300 indicates the semiconductor device according to the third embodiment.

Reference numeral 3 indicates a heat sink plate fixedly secured to the semiconductor device 300 by a sealing member 14. The heat sink plate 3 has concavo-convex portions 3A for increasing an area where it makes contact with the outside, which are provided on the surface exposed from the sealing member 14. The concavo-convex portions 3A are formed long so as to upwardly protrude from a surface 14A of the sealing member 14.

Since other portions are similar to those employed in the first or second embodiment, their description will therefore be omitted.

According to the present embodiment, since the concavo-convex portions 3A of the heat sink plate 3 are formed long so as to upwardly protrude from the surface 14A of the sealing member 14, the area where the heat sink plate 3 makes contact with the outside, further increases, so that heat generated in the semiconductor device can be dissipated earlier and with efficiency.

Since there are provided external electrode terminals on a reverse side or back 11A of a substrate 11 in the present embodiment, lots of electrode terminals can be provided without weakening their strength. Thus, even if the concavo-convex portions 3A of the heat sink plate 3 are made long to some extent and thereby the heat sink plate is made great to some extent, the semiconductor device has strength capable of enduring its load.

### Fourth Embodiment

FIG. 4 is a sectional typical view for describing a semiconductor device according to a fourth embodiment of the present invention.

In FIG. 4, reference numeral 400 indicates the semiconductor device according to the fourth embodiment.

Reference numeral 4 indicates a heat sink plate fixedly secured to the semiconductor device 400 by a sealing member 14. The heat sink plate 4 has concavo-convex portions 4A for increasing an area where it makes contact with the outside, which are provided on a surface exposed from the sealing member 14. The concavo-convex portions 4A are provided long so as to upwardly protrude from a surface 14A of the sealing member 14, thereby increasing the area thereof kept in contact with the outside.

Further, the heat sink plate 4 has a connecting portion 4B on the side opposite to the concavo-convex portions 4A, i.e., on the side opposite to a main surface 12A of a semiconductor chip. The heat sink plate 4 is disposed so as to be in contact with the main surface 12A at the surface of the connecting portion 4B.

Since other portions are similar to those employed in the first through third embodiments, their description will be omitted.

According to the present embodiment, the heat sink plate 4 and the main surface 12A corresponding to a portion most increased in the generated heat, of the semiconductor chip 12 are disposed so as to make direct contact with each other or make contact with each other through a thin protective film when the thin protective film is formed on the main surface 12A of the semiconductor chip. Accordingly, the heat generated in the main surface 12A of the semiconductor chip can be made conductive to the heat sink plate 2 directly and promptly. Further, the concavo-convex portions 4A of the heat sink plate 4 are formed long so as to protrude from the sealing member 14 to the outside, thus resulting in an increase in the area thereof kept in contact with the outside. Accordingly, the heat generated in the semiconductor device can be dissipated with more efficiency.

### Fifth Embodiment

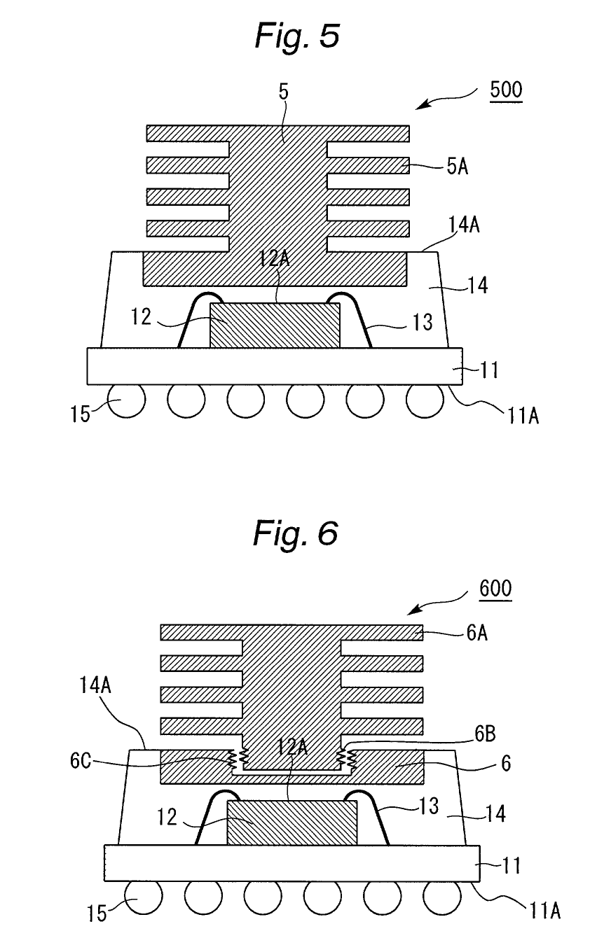

FIG. 5 is a sectional typical view for describing a semiconductor device according to a fifth embodiment of the present invention.

In FIG. 5, reference numeral 500 indicates the semiconductor device according to the fifth embodiment.

Reference numeral 5 indicates a heat sink plate. Designated at numeral 5A is a feather-shaped heat dissipation fin. The heat sink plate 5 and the heat dissipation fin 5 are integrally formed and fixedly secured to the semiconductor device 500 by a sealing member 14. The heat dissipation fin 5A is disposed so as to protrude from a surface 14A of the sealing member 14 to the outside.

Since other portions are similar to those employed in the first through fourth embodiments, their description will therefore be omitted.

Since the area at which the heat sink plate makes contact with the outside, can be made great if the heat dissipation fin 5A is used in this way, the efficiency of heat dissipation can further be enhanced.

Further, since external electrode terminals can be provided over the entire back of a substrate, a heat dissipation fin large in size to some extent can be provided without a problem of strength.

Incidentally, while the present embodiment has described the heat sink plate 5 provided with the heat dissipation fin 5A, which has not been in contact with the main surface 12A of the semiconductor chip, such a structure that the heat sink plate 5 makes contact with the semiconductor chip, may be adopted. This structure makes it possible to conduct heat faster and dissipate it with efficiency.

### Sixth Embodiment

FIG. 6 is a sectional typical view for describing a semiconductor device according to a sixth embodiment of the present invention.

In FIG. 6, reference numeral 600 indicates the semiconductor device according to the sixth embodiment.

Reference numeral 6 indicates a heat sink plate. Designated at numeral 6A is a feather-shaped heat dissipation fin. A sealing member 14 fixedly secures the heat sink plate 6 to the semiconductor device 600. Reference numerals 6B and 6C indicate engaging portions brought into engagement with each other. Designated at 6B is a screw attached to the heat dissipation fin 6A, and designated at 6C is a threaded hole defined in the heat sink plate 6. The screw 6B is threadedly inserted into its corresponding screw hole 6C for their engagement so that the heat dissipation fin 6A can be attached to the heat sink plate 6. Disengaging the screw 6B from the threaded hole 6C allows the detachment of the heat dissipation fin 6A from the heat sink plate 6.

Since other portions are similar to those employed in the first through fifth embodiments, their description will therefore be omitted.

If the heat sink plate having the detachable mechanism is used in this way, then the semiconductor device can easily be formed owing to the provision of the detachable mechanism for the conventional package.

Incidentally, while the combination of the screw and the threaded hole is used as the engaging portions used for detachment, the present invention is not limited to it. Such one that the heat dissipation fin can detachably be mounted by other means, may be used.

The features and the advantages of the present invention as described above may be summarized as follows.

According to one aspect of the present invention, in a semiconductor device, a heat sink plate is disposed at a position opposite to a main surface with elements of a semiconductor chip formed thereon, so as to adjoin the main surface. Accordingly, as compared with the case where the heat sink plate is provided on the side opposite to the main surface, the distance between the main surface of the semiconductor chip most increased in heat generated and the heat sink plate can be rendered short, and hence the heat generated in the main surface can be conducted promptly. Thus, a semiconductor device according to the present invention is capable of dissipating the generated heat efficiently and rapidly.

In another aspect, in the semiconductor device, external electrode terminals can be provided on the back of a semiconductor substrate. Accordingly, it is possible to meet the demand for the scale down and multi-functioning of the semiconductor device, reduce the entire size of the semiconductor device, and provide external electrode terminals in large numbers. Further, since it is not necessary to reduce the size of each individual external electrode terminal for the purpose of increasing the number of the external electrode terminals, a certain large heat sink plate can be mounted to the semiconductor device without a problem about its strength.

In another aspect, in the semiconductor device, a main surface of a semiconductor chip and a heat sink plate may be disposed so as to adjoin each other. Accordingly heat generated from the main surface thereof into the heat sink plate can be conducted more directly and promptly. Thus, the heat can be dissipated more efficiently.

In another aspect, in the semiconductor device, concavo-convex portions of the heat sink plate may protrude outward from the surface of a sealing member. Accordingly, the area at which a heat sink plate makes contact with the outside, can be made greater in a semiconductor device, thus, heat can be dissipated with more efficiency.

In another aspect, in a semiconductor device, a heat dissipation fin integrally may be formed with a heat sink plate. Accordingly, an area thereof kept in contact with the outside can be increased so that heat can be dissipated with efficiency.

In another aspect, in the semiconductor device, a mechanism may be able to attach a heat sink plate and a heat dissipation fin to each other and to detach them from each other. Accordingly, it can be easy to perform sealing work, fin mounting work, and fin modifying work. Thus, the semiconductor device can be manufactured with efficiency.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-211915, filed on Jul. 12, 2001 including specification, claims, drawings and summary, on which the Convention priority of the present application is based, are incorporated herein by reference in its entirety.

1. A semiconductor device comprising:
a substrate;
a semiconductor chip mounted on the substrate;
external electrodes provided on the back of the substrate, for connecting electrodes of the semiconductor chip to the outside;
a sealing member for encapsulating the semiconductor chip on the substrate; and
a heat sink plate fixed by the sealing member, wherein
the heat sink plate has concavo-convex portions formed on an exposed surface thereof and is disposed so as to be opposed to a main surface on which semiconductor elements of the semiconductor chip are formed.

2. The semiconductor device according to claim 1, wherein the heat sink plate is formed so that the convex portions protrude from the surface of the sealing member to the outside.

3. The semiconductor device according to claim 1, wherein the heat sink plate is disposed so as to adjoin the main surface with a thin sealing member placed on the main surface of the semiconductor chip being interposed therebetween.

4. The semiconductor device according to claim 3, wherein the heat sink plate is formed so that the convex portions protrude from the surface of the sealing member to the outside.

5. The semiconductor device according to claim 1, wherein the heat sink plate is disposed so as to make contact with the main surface used for the semiconductor elements.

6. The semiconductor device according to claim 5, wherein the heat sink plate is formed so that the convex portions protrude from the surface of the sealing member to the outside.

7. A semiconductor device, comprising:
a substrate;
a semiconductor chip mounted on the substrate;
external electrodes provided on the back of the substrate, for connecting electrodes of the semiconductor chip to the outside;
a sealing member for encapsulating the semiconductor chip on the substrate; and
a heat sink plate fixed by the sealing member, wherein
the heat sink plate has a heat dissipation fin formed integrally therewith.

8. The semiconductor device according to claim 7, wherein the heat sink plate and the heat dissipation fin have engaging portions brought into engagement with each other, whereby the engaging portions allow detachment of the heat dissipation fin from the heat sink plate.

9. The semiconductor device according to claim 8, wherein the engaging portions are respectively formed at the heat sink plate and the heat dissipation fin and comprise a screw and a threaded hole brought into engagement with each other.

10. The semiconductor device according to claim 7, wherein the heat sink plate is disposed so as to be opposed to a main surface on which semiconductor elements of the semiconductor chip are formed.

11. The semiconductor device according to claim 10, wherein the heat sink plate and the heat dissipation fin have engaging portions brought into engagement with each other, whereby the engaging portions allow detachment of the heat dissipation fin from the heat sink plate.

12. The semiconductor device according to claim 11, wherein the engaging portions are respectively formed at the heat sink plate and the heat dissipation fin and comprise a screw and a threaded hole brought into engagement with each other.
